(19) United States
(12) Patent Application Publication
(10) Pub. No.: US 2026/0304603 A1
(43) Pub. Date: Oct. 1, 2026

(54) CIRCUIT BOARD AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Jiaxiang ZHANG, Beijing (CN); Luoyong HU, Beijing (CN); Yuren ZHANG, Beijing (CN); Rui QIN, Beijing (CN); Yunqiao ZHANG, Beijing (CN); Bin ZHANG, Beijing (CN); Seungyong OH, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 19/479,375

(22) PCT Filed: Feb. 13, 2025
(86) PCT No.: PCT/CN2025/077151

§ 371 Date: Oct. 28, 2025

(30) Foreign Application Priority Data
Mar. 20, 2024 (CN) 202410323723.9

(51) Int. Cl. H05K 1/02

(52) U.S. Cl. CPC H05K 1/0277; H05K 2201/10128

(57) ABSTRACT

A circuit board is provided with a main body area, a bending area and a bonding area which are connected in sequence. The circuit board includes a plurality of conductive layers. The circuit board includes a first signal line, and the first signal line includes a plurality of first traces disposed in the main body area and extending in a first direction, and a second trace disposed in the bending area, with an end extending to the main body area to be connected to a first trace, and the other end extending to the bonding area. The plurality of first traces are disposed in different conductive layers, orthographic projections of at least two first traces on a reference plane overlap, and two ends of one of overlapped portions are connected to two ends of the other of the overlapped portions.

### CROSS-REFERENCE TO RELATED APPLICATIONS

This application is a national phase entry under 35 USC 371 of International Patent Application No. PCT/CN 2025/077151, filed on Feb. 13, 2025, which claims priority to Chinese Patent Application No. 202410323723.9, filed on Mar. 20, 2024, each are incorporated herein by reference in their entirety.

### TECHNICAL FIELD

The present disclosure relates to the field of display technologies, and in particular, to a circuit board and a display apparatus.

### BACKGROUND

With the development of display technologies, display apparatuses (e.g., mobile phones, notebook computers or tablet computers) are increasingly used in people's lives. Organic light-emitting diode (OLED) display apparatuses have received widespread attention due to active luminescence, wide viewing angle, high contrast, fast response speed, low power consumption, ultra-thinness and other advantages.

### SUMMARY

In an aspect, a circuit board is provided. The circuit board has a main body area, a bending area and a bonding area that are connected in sequence. The circuit board includes a plurality of conductive layers that are arranged in sequence. The circuit board includes a first signal line, and the first signal line includes a plurality of first traces and a second trace. The first traces are disposed in the main body area and extend in a first direction; the second trace is disposed in the bending area, with an end extending to the main body area and connected to a first trace, and another end extending to the bonding area. The first direction is from the main body area to the bending area. The plurality of first traces are disposed in different conductive layers; orthographic projections of at least two first traces on a reference plane overlap, and two ends of one of overlapped portions are connected to two ends of the other of the overlapped portions; the reference plane is parallel to surfaces of the conductive layers.

In some embodiments, the plurality of conductive layers include a first conductive layer and a second conductive layer. The first conductive layer includes a second signal line, the second signal line is configured to transmit a signal different from a signal which the first signal line is configured to transmit, and a line width of the second signal line is less than a sum of line widths of the plurality of first traces. The plurality of first traces include a first sub-line, and the first sub-line is disposed in the first conductive layer. The second conductive layer is disposed on a side of the first conductive layer in a third direction. The second conductive layer includes a third signal line, a line width of the third signal line is less than the sum of the line widths of the plurality of first traces, and the third signal line is configured to transmit a signal different from the signal which the first signal line is configured to transmit. The plurality of first traces further include a second sub-line, and the second sub-line is disposed in the second conductive layer. The third direction is perpendicular to the first conductive layer.

In some embodiments, an orthographic projection of the second sub-line on the reference plane overlaps an orthographic projection of the first sub-line on the reference plane.

In some embodiments, the circuit board further includes at least one insulating layer. The at least one insulating layer is disposed between the first conductive layer and the second conductive layer. The at least one insulating layer has at least one connecting hole. The second sub-line includes at least one setting line segment, and the at least one setting line segment of the second sub-line extends into the at least one connecting hole to be connected to the first sub-line.

In some embodiments, the second sub-line includes a single set line segment, and a length of the single set line segment is equal to a length of a shorter one of the first sub-line and the second sub-line.

In some embodiments, the second sub-line includes a plurality of set line segments, a length of any set line segment is less than a length of the first sub-line and less than a length of the second sub-line, and the plurality of set line segments are arranged at intervals in the first direction.

In some embodiments, the plurality of conductive layers include a first conductive layer. The first conductive layer includes a second signal line. The second signal line is configured to transmit a signal different from a signal which the first signal line is configured to transmit, and a line width of the second signal line is less than a sum of line widths of the plurality of first traces. The plurality of first traces include a first sub-line, and the first sub-line is disposed in the first conductive layer.

In some embodiments, the plurality of conductive layers include a second conductive layer. The second conductive layer includes a third signal line. A line width of the third signal line is less than a sum of line widths of the plurality of first traces, and the third signal line is configured to transmit a signal different from a signal which the first signal line is configured to transmit. The plurality of first traces include a second sub-line, and the second sub-line is disposed in the second conductive layer.

In some embodiments, the circuit board further includes a plurality of bonding pins disposed in the bonding area, and at least one bonding pin is connected to the second trace extending to the bonding area.

In some embodiments, the plurality of first traces have equal line widths.

In some embodiments, the second trace is disposed in a same layer as one of the plurality of first traces.

In some embodiments, the plurality of first traces have equal resistivities, and a line width of the second trace is greater than or equal to a sum of line widths of the plurality of first traces.

In some embodiments, at least two first traces have different resistivities, the second trace is connected to one of the plurality of first traces with a small resistivity, and a line width of the second trace is less than a sum of line widths of the plurality of first traces.

In some embodiments, the plurality of conductive layers includes a third conductive layer. The third conductive layer is different from the conductive layers where the first traces are located. The second trace is disposed in the third conductive layer.

In some embodiments, outermost conductive layers in the conductive layers where the plurality of first traces are located are a fourth conductive layer and a fifth conductive layer; and the third conductive layer is disposed on a side of one of the fourth conductive layer and the fifth conductive layer away from the other.

In some embodiments, a sum of line widths of the plurality of first traces is greater than or equal to 0.8 mm.

In some embodiments, a line width of a first trace is less than 0.8 mm.

In some embodiments, a width of the main body area of the circuit board in a second direction is in a range of 11 mm to 13 mm, inclusive; and the second direction intersects the first direction.

In another aspect, a display apparatus is provided. The display apparatus includes a display panel and the circuit board as described in any one of the above embodiments. The display panel has a display side and a non-display side that are opposite to each other. The circuit board is disposed on the non-display side of the display panel and connected to the display panel.

In some embodiments, the display apparatus further includes a driver chip, and the main body area of the circuit board is connected to the driver chip.

In some embodiments, the display panel is a flexible display panel.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals to which the embodiments of the present disclosure relate.

FIG. 1 is a structural diagram of a display apparatus, in accordance with some embodiments;

FIG. 2 is a structural diagram of another display apparatus, in accordance with some embodiments;

FIG. 3 is a structural diagram of another display apparatus, in accordance with some embodiments;

FIG. 4 is a structural diagram of a display panel including a main body portion, a bending portion and a bonding portion, in accordance with some embodiments;

FIG. 5 is a structural diagram of a display apparatus with a circuit board not being bent, in accordance with some embodiments;

FIG. 6 is a structural diagram of a display apparatus with a circuit board being bent, in accordance with some embodiments;

FIG. 7 is a structural diagram of a circuit board, in accordance with some embodiments;

FIG. 8 is a cross-sectional view taken along a section line A-A in FIG. 7;

FIG. 9 is a structural diagram of a circuit board including a first conductive layer, in accordance with some embodiments;

FIG. 10 is a structural diagram of a circuit board including a second conductive layer, in accordance with some embodiments;

FIG. 11 is a structural diagram of a second trace including a set line segment, in accordance with some embodiments;

FIG. 12 is a structural diagram of a second trace including a plurality of set line segments, in accordance with some embodiments; and

FIG. 13 is a cross-sectional view taken along a section line B-B in FIG. 7.

### DETAILED DESCRIPTION

The technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms “first” and “second” are only used for descriptive purposes, and are not to be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled”, “connected” and derivatives thereof may be used. For example, the term “connected” may be used in the description of some embodiments to indicate that two or more components are in direct physical or electrical contact with each other. As another example, the term “coupled” may be used in the description of some embodiments to indicate that two or more elements are in direct physical or electrical contact. However, the term “coupled” or “communicatively coupled” may also mean that two or more elements are not in direct contact with each other, but still cooperate or interact with each other. The embodiments disclosed herein are not necessarily limited to the contents herein.

The phrase “at least one of A, B and C” has a same meaning as the phrase “at least one of A, B or C”, and both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is optionally construed as “when” or “in a case where” or “in response to determining that” or “in response to detecting”, depending on the context. Similarly, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”, depending on the context.

The use of the phase “applicable to” or “configured to” herein means an open and inclusive expression, which does not exclude apparatuses that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value. The acceptable range of deviation is determined by a person of ordinary skill in the art in view of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of the measurement in question and errors associated with the measurement of a particular quantity (i.e., limitations of the measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thickness of layers and sizes of areas/regions are enlarged for clarity. Variations in shape with respect to the drawings due to, for example, manufacturing technologies and/or tolerances may be envisaged. Therefore, the exemplary embodiments should not be construed as being limited to the shapes of the areas/regions shown herein, but including deviations in shape due to, for example, manufacturing. For example, an etched area/region shown in a rectangular shape generally has a curved feature. Therefore, the areas/regions shown in the accompanying drawings are schematic in nature, and their shapes are not intended to show actual shapes of the areas/regions in a device, and are not intended to limit the scope of the exemplary embodiments.

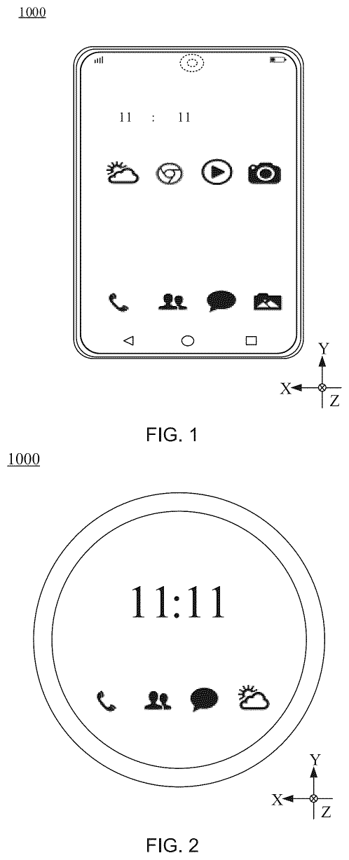

As shown in FIG. 1, some embodiments of the present disclosure provide a display apparatus 1000, and the display apparatus 1000 may be any apparatus that displays images whether in motion (e.g., a video) or stationary (e.g., a static image), and regardless of text or image.

For example, the display apparatus 1000 may be any product or component having a display function, such as a television, a notebook computer, a tablet computer, a mobile phone, a personal digital assistant (PDA), a navigator, a wearable device, an augmented reality (AR) device, a virtual reality (VR) device, a car mounted display or a flight display.

In some examples, as shown in FIG. 1, the display apparatus 1000 may be a portable display product. For example, the display apparatus 1000 is a mobile phone shown in FIG. 1.

In some other examples, as shown in FIG. 2, the display apparatus 1000 may be a wearable device. For example, the display apparatus 1000 is a watch shown in FIG. 2.

Some embodiments of the present disclosure will be schematically described below by considering an example in which the display apparatus is a mobile phone, but the embodiments of the present disclosure are not limited thereto. A case where the display apparatus is a watch may also be taken into consideration as long as the same technical concept is applied.

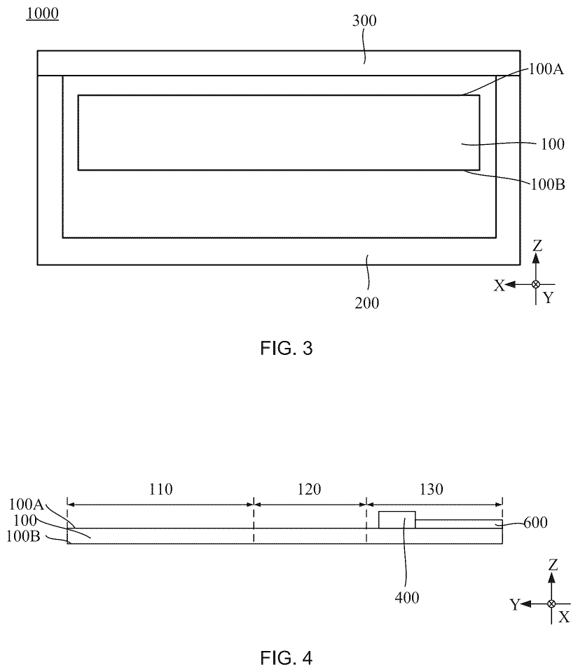

In some embodiments, as shown in FIG. 3, the display apparatus 1000 includes a display panel 100, a housing 200 and a cover plate 300.

The display panel 100 has a display side 100A and a non-display side 100B that are opposite to each other. The display side 100A refers to a side of the display panel 100 capable of emitting light (an upper side of the display panel 100 in FIG. 3), and the non-display side 100B refers to the other side opposite to the display side 100A (a lower side of the display panel 100 in FIG. 3).

The type of the display panel 100 varies, and may be selected depending on actual needs.

For example, the display panel 100 may be an organic light-emitting diode (OLED) display panel, a quantum dot light-emitting diode (QLED) display panel, an active matrix organic light-emitting diode (AMOLED) display panel, a liquid crystal display (LCD) panel, or a mini/micro light-emitting display (MLED) panel, and limitations are not specifically made here in the embodiments of the present disclosure.

As shown in FIG. 3, the housing 200 may have a box-shaped structure with an opening. The display panel 100 may be provided within the housing 200. The cover plate 300 is disposed on the display side of the display panel 100 and located at the opening of the housing 200.

As shown in FIG. 3, a longitudinal section of the housing 200 is, for example, in a U shape. The display panel 100 is provided within the housing 200, and the cover plate 300 is provided at the opening of the housing 200.

In some embodiments, as shown in FIG. 4, the display panel 100 is a flexible display panel. The display panel 100 includes a main body portion 110, a bending portion 120 and a bonding portion 130 that are connected in sequence. In a second direction Y, the bending portion 120 is located on a side of the main body portion 110, and the bonding portion 130 is located on a side of the bending portion 120 away from the main body portion 110. That is, the bending portion 120 is located between the main body portion 110 and the bonding portion 130.

The main body portion 110 may be a portion of the display panel 100 for displaying images. As shown in FIG. 4, the main body portion 110 has a display side 100A and a non-display side 100B that are opposite to each other. It will be noted that the display side 100A refers to a side of the main body portion 110 that displays an image (an upper side of the main body portion 110 in FIG. 4), and the non-display side 100B refers to the other side opposite to the display side 100A (a lower side of the main body portion 110 in FIG. 4).

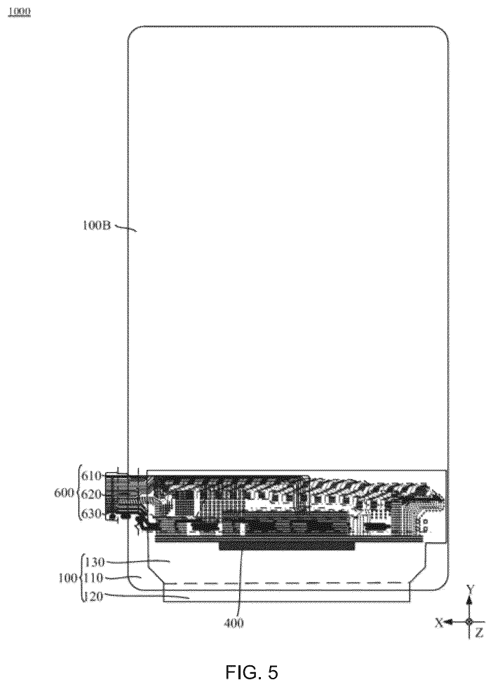

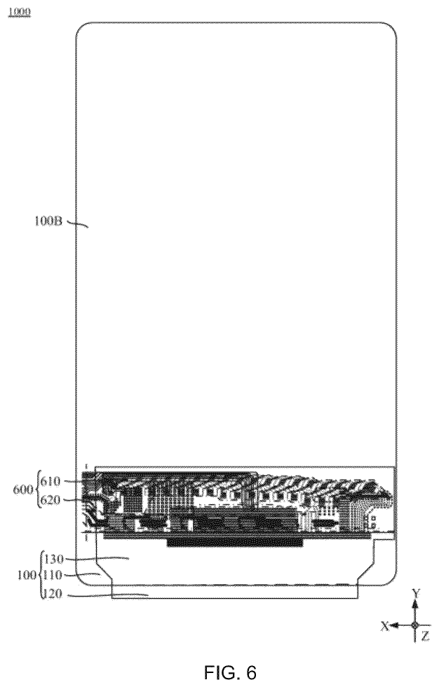

Through a bending process, as shown in FIGS. 5 and 6, the bending portion 120 may be bent along a bending axis extending in a first direction X toward the non-display side 100B of the main body portion 110 of the display panel 100, so that the bonding portion 130 is bent to the non-display side 100B of the main body portion 110, thereby reducing a frame of the display apparatus 1000 (as shown in FIGS. 1 and 2). The bending axis is not an actual structure existing in the display panel 100, and is only a concept proposed to illustrate the bending process of the display panel 100.

On this basis, as shown in FIGS. 4, 5 and 6, the display apparatus 1000 further includes a driver chip 400, and the driver chip 400 may be provided on the bonding portion 130. As shown in FIGS. 5 and 6, in a case where the display panel 100 is in a bent state, the driver chip 400 is provided on a side of the bonding portion 130 away from the main body portion. The driver chip 400 is configured to provide data signals required for displaying the image to the main body portion 110 through the bonding portion 130 and the bending portion 120, so as to control the display panel 100 to display the image.

The driver chip 400 includes at least one of a source driver chip, a touch chip, a timing controller, a gamma circuit and other microchips, and limitations are not specifically made here in the embodiments of the present disclosure.

In some embodiments, as shown in FIGS. 4, 5 and 6, the display apparatus 1000 further includes a circuit board 600. In a third direction Z, the circuit board 600 is provided on a side of the driver chip 400 proximate to the bonding portion 130, that is, the circuit board 600 and the driver chip 400 are provided on the same side of the bonding portion 130. In the second direction Y, the circuit board 600 is provided on a side of the driver chip 400 away from the bending portion 120, and the circuit board 600 is provided on the bonding portion 130. The circuit board 600 is connected to the driver chip 400 and the bonding portion 130, so that the driver chip 400 may provide the display panel 100 with the data signals required for displaying the image through the circuit board 600.

In some examples, as shown in FIG. 5, the circuit board 600 has a main body area 610, a bending area 620 and a bonding area 630 that are sequentially connected.

In an unfolded state, the main body area 610, the bending area 620 and the bonding area 630 are arranged in the first direction X. In the first direction X, a length of the circuit board 600 is greater than a width of the display panel 100. As shown in FIG. 6, in a bent state, the bending area 620 of the circuit board 600 bends toward a side of the main body area 610 of the circuit board 600 proximate to the bonding portion 130, so that the bonding area 630 of the circuit board 600 is bent to the side of the main body area 610 of the circuit board 600 proximate to the bonding portion 130. In this way, in the first direction X, the length of the circuit board 600 is less than the width of the display panel 100, and thus the circuit board 600 will not affect installation of the display panel 100 and the housing 200.

As shown in FIG. 6, the main body area 610 of the circuit board 600 is connected to the driver chip 400, and the bonding area 630 of the circuit board 600 is connected to the bonding portion 130. In this way, the driver chip 400 provides the data signals required for displaying the image to the main body portion 110 through the bonding portion 130 and the bending portion 120, so as to control the display panel 100 to display the image.

In some examples, as shown in FIG. 5, in the second direction Y, a width of the main body area 610 is greater than a width of the bonding area 630, and greater than a width of the bending area 620 in the second direction Y. The second direction Y and the first direction X intersect, for example, the first direction X and the second direction Y are perpendicular.

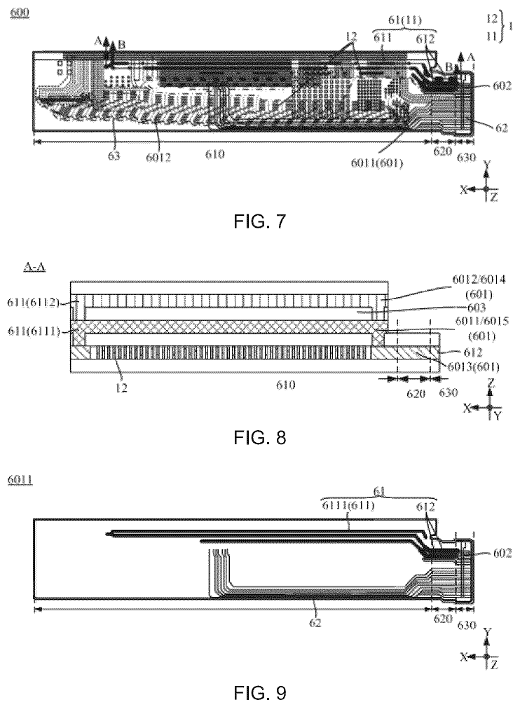

In some embodiments, as shown in FIG. 7, the circuit board 600 includes a plurality of conductive layers 601 that are arranged in sequence.

For example, the circuit board 600 includes two conductive layers 601 that are arranged in sequence, three conductive layers 601 that are arranged in sequence, four conductive layers 601 that are arranged in sequence, five conductive layers 601 that are arranged in sequence or eight conductive layers 601 that are arranged in sequence, and limitations are not specifically made here in the embodiments of the present disclosure.

For example, a material of the conductive layer 601 includes metal. For example, the material of the conductive layer 601 includes copper or silver. In this way, the circuit board 600 may have a good conductivity and a low resistance.

The circuit board 600 further includes a plurality of signal lines 1. The plurality of signal lines 1 are disposed in the plurality of conductive layer 601. For example, the plurality of signal lines 1 include at least one of a signal line for transmitting a first power signal, a signal line for transmitting a second power signal, a signal line for transmitting a touch signal, a signal line for transmitting a communication protocol, a signal line for transmitting a data signal, a signal line for transmitting a reset signal and a signal line for transmitting a logic signal.

As shown in FIG. 7, the plurality of signal lines 1 includes first-type signal lines 11 and second-type signal lines 12. The first-type signal lines 11 need to carry relatively large currents. For example, the first-type signal lines 11 include at least one of a signal line for transmitting a first power signal, a signal line for transmitting a second power signal and a signal line for transmitting a logic signal.

The second-type signal lines 12 need to carry relatively small currents. For example, the second-type signal lines 12 include at least one of a signal line for transmitting a touch signal, a signal line for transmitting a communication protocol, a signal line for transmitting a data signal and a signal line for transmitting a reset signal.

In the related art, the first-type signal lines include a first signal line, and the first signal line includes a first trace and a second trace. The first trace is provided in the main body area. The second trace is provided in the bending area, with an end extending to the main body area and connected to the first trace, and the other end extending to the bonding area. The first trace is provided in a conductive layer and needs to carry a relatively large current. Therefore, a line width of the first trace is relatively large (e.g., greater than or equal to 0.8 mm, such as 1 mm). The relatively wide first trace results in a relatively large width of the main body area of the circuit board in the second direction, thereby causing the circuit board to occupy a relatively large space in the display apparatus.

In order to solve the above technical problems, some embodiments of the present disclosure provide a circuit board 600. As shown in FIG. 7, a first signal line 61 includes a plurality of first traces 611 and a second trace 612. For example, the first signal line 61 includes two, three, four, five or six first traces 611.

Some embodiments of the present disclosure will be schematically described below by considering an example in which the first signal line 61 includes two first traces 611, but the embodiments of the present disclosure are not limited thereto. A case where the first signal line 61 includes four or six first traces 611 may also be taken into consideration as long as the same technical concept is applied.

As shown in FIG. 7, the first trace 611 is disposed in the main body area 610 and extends in the first direction X. The second trace 612 is disposed in the bending area 620, with an end extending to the main body area 610 and connected to the first trace 611, and the other end extending to the bonding area 630. As shown in FIG. 8, the plurality of first traces 611 are disposed in different conductive layers 601. Orthographic projections of at least two first traces 611 on a reference plane overlap, and two ends of one of the overlapped portions are connected to two ends of the other of the overlapped portions. It can be understood that in the plurality of first traces 611, ends of first traces 611, orthographic projections of which are not overlapped, away from the second trace 612 are connected.

That is to say, the first trace in the related art is split into a plurality of first traces 611, and the plurality of first traces 611 are arranged in parallel. A total current that the plurality of first traces 611 arranged in parallel need to carry is equal to the current that the first trace in the related art need to carry, that is, the current that the first trace 611 provided in some embodiments of the present disclosure need to carry is less than the current that needs to be carried in the related art. Therefore, a line width of the first trace 611 provided in some embodiments of the present disclosure is less than a line width of the first trace in the related art, and a sum of line widths of the plurality of first traces 611 provided in some embodiments of the present disclosure is equal to the line width of the first trace in the related art. In the second direction Y, the first traces 611 with the overlapped orthographic projections share a part of space, and thus a width of the plurality of first traces 611 in the second direction Y may be reduced, and a width of the main body area 610 of the circuit board 600 in the second direction Y may be reduced. Furthermore, the space occupied by the circuit board 600 may be reduced, thereby increasing the space for other components in the display apparatus (e.g., battery and antenna which are arranged opposite to the main body area 610 of the circuit board 600).

It can be seem from experiments that compared with the circuit board in the related art, in some embodiments of the present disclosure, a reduction in width of the main body area 610 of the circuit board 600 in the second direction Y is greater than or equal to 1.5 mm, such as 1.5 mm, 1.7 mm or 2 mm.

In some examples, the width of the main body area 610 of the circuit board 600 in the second direction Y is reduced from a range of 14 mm to 16 mm to a range of 11 mm to 13 mm.

For example, the width of the circuit board 600 in the second direction Y is 11 mm, 12 mm or 13 mm.

For example, the space occupied by the battery increases. In this way, the battery can be made relatively large, thereby increasing the battery capacity, which is beneficial to increasing the standby time of the display apparatus 1000. Alternatively, for example, the space occupied by the antenna increases. In this way, the antenna can be made relatively large, thereby increasing an effective area of the antenna, which is beneficial to improving transmission power or reception power of the antenna.

As shown in FIG. 8, the second trace 612 is disposed in a conductive layer 601. In this way, a thickness of the bending area 620 of the circuit board 600 is relatively small, so that the bending area 620 of the circuit board 600 has a good flexibility. When the circuit board 600 is bent, the good flexibility of the bending area 620 of the circuit board 600 may reduce a bending stress of the circuit board 600.

In some embodiments, orthographic projections of any two first traces 611 on the reference plane overlap, and two ends of one of the overlapped portions are connected to two ends of the other of the overlapped portions. In this way, the width of the plurality of first traces 611 in the second direction Y may further be reduced, and the width of the main body area 610 of the circuit board 600 in the second direction Y may be reduced.

In some embodiments, as shown in FIGS. 7 and 8, the first signal line 61 includes two first traces 611 and a second trace 612. In the first direction X, ends of the two first traces 611 are flush with each other and are connected with each other, and other ends of the two first traces 611 are flush with each other and are connected with each other. Orthographic projections of the two first traces 611 on the reference plane overlap.

In some embodiments, as shown in FIG. 7, the circuit board 600 further includes a plurality of bonding pins 602. The plurality of bonding pins 602 are disposed in the bonding area 630, and at least one bonding pin 602 is connected to the second trace 612 extending to the bonding area 630.

In some embodiments, as shown in FIGS. 7 and 8, the plurality of conductive layers 601 include a first conductive layer 6011 and/or a second conductive layer 6012.

As shown in FIGS. 7, 8 and 9, in a case where the plurality of conductive layers 601 include a first conductive layer 6011, the first conductive layer 6011 includes a second signal line 62. The signal transmitted by the second signal line 62 is different from the signal transmitted by the first signal line 61. For example, the second signal line 62 is used to transmit a touch signal or a communication protocol. A line width of the second signal line 62 is less than a sum of the line widths of the plurality of first traces 611, that is, the line width of the second signal line 62 is relatively narrow. The relatively narrow signal line will not lead to a relatively large width of the circuit board 600 in the second direction Y. Therefore, there is no need to split the second signal line 62, that is, the second signal line 62 is only provided in the first conductive layer 6011. In other words, the first conductive layer 6011 is an originally provided conductive layer 601 instead of a new conductive layer 601 provided for the first trace 611 after the split.

As shown in FIGS. 7, 8 and 9, the plurality of first traces 611 include a first sub-lines 6111, and the first sub-line 6111 is provided in the first conductive layer 6011. That is, the first sub-line 6111 and the second signal line 62 are made of the same material and disposed in the same layer. In this way, the thickness of the circuit board 600 may be reduced, which is conducive to reducing the thickness of the display apparatus 1000.

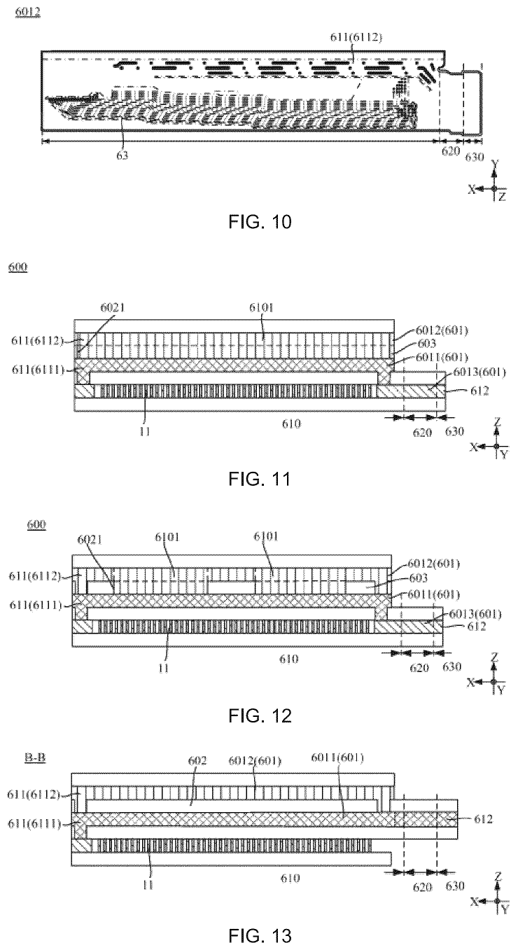

As shown in FIGS. 7, 8 and 10, in a case where the plurality of conductive layers 601 further include a second conductive layer 6012 the second conductive layer 6012 is disposed on a side of the first conductive layer 6011 in the third direction Z, where the third direction Z is perpendicular to the first conductive layer 6011.

Here, the second conductive layer 6012 includes a third signal line 63. The signal transmitted by the third signal line 63 is different from the signal transmitted by the first signal line 61. For example, the third signal line 63 is used for grounding. A line width of the third signal line 63 is less than a sum of the line widths of the plurality of first traces 611, that is, the line width of the third signal line 63 is relatively narrow. The relatively narrow signal line will not lead to a relatively large width of the circuit board 600 in the second direction Y. Therefore, there is no need to split the third signal line 63, that is, the third signal line 63 is only provided in the second conductive layer 6012. In other words, the second conductive layer 6012 is an originally provided conductive layer 601 instead of a new conductive layer 601 provided for the first trace 611 after the split.

As shown in FIGS. 7, 8 and 10, the plurality of first traces 611 include a second sub-line 6112, and the second sub-line 6112 is provided in the second conductive layer 6012. That is, the second sub-line 6112 and the third signal line 63 are made of the same material and disposed in the same layer. In this way, the thickness of the circuit board 600 may further be reduced, which is conducive to reducing the thickness of the display apparatus 1000.

In some examples, as shown in FIG. 8 the plurality of conductive layers 601 include a first conductive layer 6011 and a second conductive layer 6012. The circuit board 600 includes two first traces 611, that is, the plurality of first traces 611 only include a first sub-line 6111 and a second sub-line 6112. The first sub-line 6111 is disposed in the first conductive layer 6011, and the second sub-line 6112 is disposed in the second conductive layer 6012. In this way, there is no need to add a new conductive layer 601, and the thickness of the circuit board 600 may be kept unchanged.

In some embodiments, as shown in FIGS. 11 and 12, an orthographic projection of the second sub-line 6112 on the reference plane overlaps an orthographic projection of the first sub-line 6111 on the reference plane. The circuit board 600 further includes at least one insulating layer 603. The at least one insulating layer 603 is provided between the first conductive layer 6011 and the second conductive layer 6012, and the at least one insulating layer 603 has connecting holes 6021. The second sub-line 6112 includes a setting line segment 6101, and the setting line segment 6101 of the second sub-line 6112 extends into a connecting hole 6021 to be connected to the first sub-line 6111. In this way, the electrical connection between the first sub-line 6111 and the second sub-line 6112 may be made secure, and moreover, a total resistance of the first sub-line 6111 and the second sub-line 6112 may be reduced, thereby reducing a total resistance of the plurality of first traces 611.

For example, the first conductive layer 6011 and the second conductive layer 6012 are adjacent conductive layers. Alternatively, for example, at least one conductive layer 601 is provided between the first conductive layer 6011 and the second conductive layer 6012, and the circuit board 600 includes a plurality of insulating layers 603.

In some examples, as shown in FIG. 11, the second sub-line 6112 includes a set line segment 6101, and a length of the set line segment 6101 is equal to a length of the shorter one of the first sub-line 6111 and the second sub-line 6112.

In some other examples, as shown in FIG. 12, the second sub-line 6112 includes a plurality of set line segments 6101, a length of any of the set line segments 6101 is less than a length of the first sub-line 6111 and less than a length of the second sub-line 6112, and the plurality of set line segments 6101 are arranged at intervals in the first direction X.

In some embodiments, the line widths of the plurality of first traces 611 are equal, so that a difference in resistance between the plurality of first traces 611 may be reduced, thereby reducing a difference in timing of signals transmitted by the plurality of first traces 611.

On this basis, in the second direction Y, edges of orthographic projections of at least two first traces 611 on the reference plane coincide. In this way, space shared by the first traces 611 with overlapped orthographic projections increases, thereby further reducing the width of the plurality of first traces 611 in the second direction Y and reducing the width of the main body area 610 of the circuit board 600 in the second direction Y.

In some other embodiments, line widths of at least two first traces 611 are unequal. For example, line widths of any two first traces 611 are unequal. The width of the first trace 611 included in each conductive layer 601 can be set depending on actual conditions.

In some embodiments, as shown in FIG. 13, the second trace 612 is disposed in the same layer as a first trace 611, that is, the second trace 612 is made of the same material and disposed in the same layer as the first trace 611. In this way, the thickness of the circuit board 600 may be reduced, which is beneficial to reducing the thickness of the display apparatus 1000.

It can be understood that the current carried by the second trace 612 is equal to a sum of the currents carried by the plurality of first traces 611. Therefore, the line width of the second trace 612 is greater than a line width of the first trace 611 disposed in the same layer as the second trace 612.

In some examples, the plurality of first traces 611 have equal resistivities, that is, the plurality of first traces 611 have the same materials. The line width of the second trace 612 is greater than or equal to a sum of the line widths of the plurality of first traces 611. In this way, consistency of the materials in the circuit board 600 may be improved, and the manufacturing cost of the circuit board 600 may be reduced.

In some other examples, at least two first traces 611 have different resistivities, that is, the at least two first traces 611 have different materials. The second trace 612 is connected to one of the plurality of first traces 611 with a relatively small resistivity, and the line width of the second trace 612 is less than a sum of the line widths of the plurality of first traces 611. In this way, the line width of the second trace 612 may be reduced, and widths of the bending area 620 and the bonding area 630 of the circuit board 600 in the second direction Y may be reduced, thereby reducing the space occupied by the circuit board 600.

In some other embodiments, as shown in FIGS. 11 and 12, the plurality of conductive layers 601 further include a third conductive layer 6013. The third conductive layer 6013 and the conductive layers 601 where the first traces 611 are located are different conductive layers 601, and the second trace 612 is disposed in the third conductive layer 6013.

The third conductive layer 6013 may be disposed between two adjacent conductive layers 601 in multiple conductive layers 601 where the first traces 611 are located, or may be disposed on a side of the multiple conductive layers 601 where the first traces 611 are located in the third direction Z. The third direction Z is perpendicular to the conductive layer 601.

In some examples, as shown in FIG. 8, the outermost conductive layers 601 in the multiple conductive layers 601 where the plurality of first traces 611 are located are a fourth conductive layer 6014 and a fifth conductive layer 6015. The third conductive layer 6013 is disposed on a side of one of the fourth conductive layer 6014 and the fifth conductive layer 6015 away from the other.

For example, the third conductive layer 6013 is disposed on a side of the fourth conductive layer 6014 away from the fifth conductive layer 6015. Alternatively, for example, the third conductive layer 6013 is disposed on a side of the fifth conductive layer 6015 away from the fourth conductive layer 6014.

On this basis, the third conductive layer 6013 is disposed on a side of the fourth conductive layer 6014 and the fifth conductive layer 6015 proximate to the bonding portion 130. In this way, a bending radius of the circuit board 600 may be reduced, which is beneficial to increasing a distance between the housing 200 and the bending area 620 of the circuit board 600, thereby reducing an impact of the circuit board 600 on the housing 200.

As shown in FIG. 8, in a case where the circuit board 600 includes two first traces 611, the fourth conductive layer 6014 may be one of the first conductive layer 6011 and the second conductive layer 6012, and the fifth conductive layer 6015 may be the other of the first conductive layer 6011 and the second conductive layer 6012.

In some embodiments, a sum of the line widths of the plurality of first traces 611 is greater than or equal to 0.8 mm. For example, the sum of the line widths of the plurality of first traces 611 is 0.8 mm, 1 mm or 1.5 mm. That is, in a case where the line widths of the signal lines are greater than or equal to 0.8 mm, the signal lines will lead to a relatively wide main body area 610 of the circuit board 600 in the second direction Y, thereby causing a large space occupied by the circuit board in the display apparatus. Therefore, the signal line needs to be configured as described above, i.e., the signal line is split into a plurality of first traces 611, so as to reduce the width of the main body area 610 of the circuit board 600 in the second direction Y.

In some embodiments, a line width of the first trace 611 is less than 0.8 mm. For example, the line width of the first trace 611 is 0.05 mm, 0.1 mm, 0.2 mm, 0.3 mm, 0.4 mm, 0.5 mm, 0.6 mm, 0.7 mm or 0.75 mm.

That is, splitting a wide signal line into signal lines each with a line width less than 0.8 mm may reduce the width of the main body area 610 of the circuit board 600 in the second direction Y.

In the description of the specification, specific features, structures, materials or characteristics may be combined in any one or more embodiments or examples in any suitable manner.

The foregoing descriptions are merely specific implementations of the present disclosure, but the protection scope of the present disclosure is not limited thereto. Variations or substitutions that those skilled in the art could conceive of within the technical scope of the present disclosure shall fall within the protection scope of the present disclosure. Therefore, the protection scope of the present disclosure shall be subject to the protection scope of the claims.

1. A circuit board having a main body area, a bending area and a bonding area that are connected in sequence; the circuit board comprising a plurality of conductive layers that are arranged in sequence, wherein
the circuit board comprises a first signal line, the first signal line includes a plurality of first traces and a second trace; the first traces are disposed in the main body area and extend in a first direction; the second trace is disposed in the bending area, with an end extending to the main body area and connected to a first trace, and another end extending to the bonding area; the first direction is from the main body area to the bending area; and
the plurality of first traces are disposed in different conductive layers; orthographic projections of at least two first traces on a reference plane overlap, and two ends of one of overlapped portions are connected to two ends of the other of the overlapped portions; the reference plane is parallel to surfaces of the conductive layers.

2. The circuit board according to claim 1, wherein the plurality of conductive layers include:
a first conductive layer including a second signal line, wherein the second signal line is configured to transmit a signal different from a signal which the first signal line is configured to transmit, and a line width of the second signal line is less than a sum of line widths of the plurality of first traces; the plurality of first traces include a first sub-line, and the first sub-line is disposed in the first conductive layer; and
a second conductive layer disposed on a side of the first conductive layer in a third direction, wherein the second conductive layer includes a third signal line, a line width of the third signal line is less than the sum of the line widths of the plurality of first traces;
the third signal line is configured to transmit a signal different from the signal which the first signal line is configured to transmit; the plurality of first traces further include a second sub-line, and the second sub-line is disposed in the second conductive layer; the third direction is perpendicular to the first conductive layer.

3. The circuit board according to claim 2, wherein an orthographic projection of the second sub-line on the reference plane overlaps an orthographic projection of the first sub-line on the reference plane; and
the circuit board further comprises:
at least one insulating layer disposed between the first conductive layer and the second conductive layer, wherein the at least one insulating layer has at least one connecting hole; the second sub-line includes at least one setting line segment, and the at least one setting line segment of the second sub-line extends into the at least one connecting hole to be connected to the first sub-line.

4. The circuit board according to claim 3, wherein the second sub-line includes a single set line segment, and a length of the single set line segment is equal to a length of a shorter one of the first sub-line and the second sub-line.

5. The circuit board according to claim 3, wherein the second sub-line includes a plurality of set line segments, a length of any set line segment is less than a length of the first sub-line and less than a length of the second sub-line, and the plurality of set line segments are arranged at intervals in the first direction.

6. The circuit board according to claim 1, wherein the plurality of first traces have equal line widths.

7. The circuit board according to claim 1, wherein the second trace is disposed in a same layer as one of the plurality of first traces.

8. The circuit board according to claim 7, wherein the plurality of first traces have equal resistivities, and a line width of the second trace is greater than or equal to a sum of line widths of the plurality of first traces.

9. The circuit board according to claim 7, wherein at least two first traces have different resistivities, the second trace is connected to one of the plurality of first traces with a small resistivity, and a line width of the second trace is less than a sum of line widths of the plurality of first traces.

10. The circuit board according to claim 1, wherein the plurality of conductive layers includes:
a third conductive layer that is different from the conductive layers where the first traces are located; the second trace being disposed in the third conductive layer.

11. The circuit board according to claim 10, wherein outermost conductive layers in the conductive layers where the plurality of first traces are located are ta fourth conductive layer and a fifth conductive layer; and the third conductive layer is disposed on a side of one of the fourth conductive layer and the fifth conductive layer away from the other.

12. The circuit board according to claim 1, wherein a sum of line widths of the plurality of first traces is greater than or equal to 0.8 mm.

13. The circuit board according to claim 1, wherein a line width of a first trace is less than 0.8 mm.

14. The circuit board according to claim 1, wherein a width of the main body area of the circuit board in a second direction is in a range of 11 mm to 13 mm, inclusive; and the second direction intersects the first direction.

15. A display apparatus, comprising:
a display panel having a display side and a non-display side that are opposite to each other; and
the circuit board according to claim 1, wherein the circuit board is disposed on the non-display side of the display panel and connected to the display panel.

16. The circuit board according to claim 1, wherein the plurality of conductive layers include:
a first conductive layer including a second signal line, wherein the second signal line is configured to transmit a signal different from a signal which the first signal line is configured to transmit, and a line width of the second signal line is less than a sum of line widths of the plurality of first traces; the plurality of first traces include a first sub-line, and the first sub-line is disposed in the first conductive layer.

17. The circuit board according to claim 1, wherein the plurality of conductive layers include:
a second conductive layer including a third signal line, wherein a line width of the third signal line is less than a sum of line widths of the plurality of first traces; the third signal line is configured to transmit a signal different from a signal which the first signal line is configured to transmit; the plurality of first traces include a second sub-line, and the second sub-line is disposed in the second conductive layer.

18. The circuit board according to claim 1, further comprising a plurality of bonding pins disposed in the bonding area, wherein at least one bonding pin is connected to the second trace extending to the bonding area.

19. The display apparatus according to claim 15, further comprising a driver chip, wherein the main body area of the circuit board is connected to the driver chip.

20. The display apparatus according to claim 15, wherein the display panel is a flexible display panel.
